(19) United States
(12) Patent Application Publication
(10) Pub. No.: US 2026/0297468 A1
(43) Pub. Date: Oct. 1, 2026

(54) CLEANING COMPOSITION AND METHOD OF FORMING PHOTORESIST PATTERN USING THE SAME

(71) Applicant: DONGWOO FINE-CHEM CO., LTD., Jeonbuk-do (KR)

(72) Inventors: BAEK HYUN CHO, Jeonbuk-do (KR); GI JIN KWUN, Jeonbuk-do (KR); HYUNG SUB CHOI, Jeonbuk-do (KR)

(21) Appl. No.: 19/576,287

(22) Filed: Mar. 24, 2026

(30) Foreign Application Priority Data
Mar. 25, 2025 (KR) 10-2025-0038340

(51) Int. Cl. C11D 7/50; C11D 7/26; C11D 7/32; G03F 7/40; G03F 7/42; H10P 76/00

(52) U.S. Cl. CPC C11D 7/5022; C11D 7/264; C11D 7/266; C11D 7/3263; G03F 7/40; G03F 7/422; H10P 76/00

(57) ABSTRACT

A cleaning composition includes an alcohol-based solvent, and an unsaturated carbonyl compound. A content of the unsaturated carbonyl compound is greater than 0, and 1 ppb or less based on a total weight of the composition. The cleaning composition provides improved pattern stability and enhanced capability of removing photoresist residues and watermarks.

### CROSS-REFERENCE TO RELATED APPLICATION AND CLAIM OF PRIORITY

This application claims priority to Korean Patent Application No. 10-2025-0038340 filed on Mar. 25, 2025, the entire disclosures of which are incorporated by reference herein.

### BACKGROUND

### 1. Field

The present invention relates to a cleaning composition and a method for forming a photoresist pattern using the same.

### 2. Description of the Related Art

A composition containing an alcohol-based solvent can be used for cleaning an electronic device such as a semiconductor device or may be used for removing photoresist residues during a photo-lithography process in a semiconductor device manufacture process.

For example, a photoresist composition may be applied to a semiconductor substrate, and then soft-baked to form a photoresist layer. Subsequently, the photoresist layer may be partially removed by exposure and development processes to form a photoresist pattern. An etching process using the photoresist pattern as an etching mask may be performed to form wirings, electrodes, insulating patterns, or the like, of the semiconductor device.

As described above, the photoresist pattern may be formed by the exposure and development processes, and then photoresist residues on the semiconductor substrate may be removed using a cleaning solution. However, However, additional contaminations or defects may be caused on the semiconductor substrate by the cleaning solution.

### SUMMARY

According to an aspect of the present invention, there is provided a cleaning composition providing improved cleaning capability and pattern reliability.

According to an aspect of the present invention, there is provided a method of forming a photoresist pattern using the cleaning composition.

(1) A cleaning composition, including: an alcohol-based solvent; and an unsaturated carbonyl compound, wherein a content of the unsaturated carbonyl compound is greater than 0, and 1 ppb or less based on a total weight of the composition.

(2) The cleaning composition of the above (1), wherein the content of the unsaturated carbonyl compound is in a range from 0.1 ppt to 1 ppb based on the total weight of the composition.

(3) The cleaning composition of the above (1), wherein the unsaturated carbonyl compound has 3 to 10 carbon atoms.

(4) The cleaning composition of the above (1), wherein the unsaturated carbonyl compound includes at least one selected from the group consisting of mesityl oxide, methyl vinyl ketone, acrolein, methyl acrylate, acrylamide, maleic acid and fumaric acid.

(5) The cleaning composition of the above (1), wherein the unsaturated carbonyl compound includes mesityl oxide.

(6) The cleaning composition of the above (1), wherein the alcohol-based solvent includes an alcohol having 2 to 5 carbon atoms.

(7) The cleaning composition of the above (1), wherein the alcohol-based solvent includes at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.

(8) The cleaning composition of the above (1), wherein the alcohol-based solvent includes 2-propanol.

(9) The cleaning composition of the above (8), wherein the alcohol-based solvent further includes at least one selected from the group consisting of ethanol, 1-propanol, 1-butanol and 1-pentanol.

(10) The cleaning composition of the above (1), wherein a boiling point of the alcohol-based solvent is 110° C. or less, and a vapor pressure of the alcohol-based solvent at 25° C. is 0.5 kPa or higher.

(11) The cleaning composition of claim 1, wherein a content of the alcohol-based solvent is 99 wt % or more, and less than 100 wt % based on the total weight of the composition.

(12) A method of forming a photoresist pattern, including: forming a photoresist layer on a substrate; partially removing the photoresist layer to form a photoresist pattern; and cleaning the substrate on which the photoresist pattern is formed using the above-described cleaning composition.

(13) The method of the above (12), further including washing the substrate on which the photoresist pattern is formed with water prior to the cleaning using the cleaning composition.

Photoresist residues generated after a development process may be effectively removed using a cleaning composition according to embodiments of the present invention. Further, damages to the photoresist pattern during a cleaning process may be prevented to achieve a uniform pattern profile.

In example embodiments, the cleaning composition may include an unsaturated carbonyl compound, and may effectively suppress or reduce water marks caused by the cleaning composition.

Accordingly, a high-resolution target pattern having desired pattern spacing and size may be stably formed by a photo-lithography process using the photoresist pattern.

### BRIEF DESCRIPTION OF THE DRAWINGS

FIGS. 1 to 4 are schematic cross-sectional views illustrating a method of forming a pattern in accordance with example embodiments.

### DETAILED DESCRIPTION OF THE EMBODIMENTS

Embodiments of the present invention provide a cleaning composition including an alcohol-based solvent and an unsaturated carbonyl compound. Further, a method of forming a photoresist pattern using the cleaning composition is provided.

The term “ppb” used herein refers to “parts-per-billion (10⁻⁹)” and “ppt” used herein refers to “parts-per-trillion (10⁻¹²)”, and the ppb and ppt may refer to a weight-based content.

Hereinafter, embodiments of the present invention will be described in detail.

### <Cleaning Composition>

A cleaning composition (hereinafter, that may be abbreviated as a composition) according to example embodiments may include an alcohol-based solvent and an unsaturated carbonyl compound.

The alcohol-based solvent may remove process residues such as an undeveloped photoresist or a residual developer present on a semiconductor substrate. For example, organic and inorganic residues present between photoresist patterns after exposure and development processes may be effectively removed from the semiconductor substrate using the alcohol-based solvent included in the cleaning composition.

In some embodiments, the alcohol-based solvent may include an alcohol having 2 to 5 carbon atoms.

For example, the alcohol-based solvent may include ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol, 2,2-dimethyl-1-propanol, or the like. These may be used alone or in a combination of two or more therefrom.

For example, methanol has a high volatility to have low cleaning capability and stability. An alcohol having more than 5 carbon atoms may remain on a surface of a semiconductor substrate after cleaning. Thus, when the alcohol-based solvent includes an alcohol having 2 to 5 carbon atoms, defects during a semiconductor device fabrication may be reduced.

In example embodiments, the alcohol-based solvent may be obtained by refining a crude material. A purity of the alcohol-based solvent may be improved by the refining process.

For example, 2-propanol derived from a fossil resource such as coal, oil, natural gas, etc., as a raw material before the refinement may be used as the alcohol-based solvent, and 2-propanol (Bio-2-propanol) derived from a biomass may be used.

Examples of Bio-2-propanol include 2-propanol obtained using bacteria capable of producing 2-propanol from a biomass material (see International Patent Publication No. 2009/008377), 2-propanol obtained by hydrating propylene obtained using a biomethanol, 2-propanol obtained by reducing acetone obtained using bioethanol, 2-propanol obtained by hydrating propylene obtained using bioethanol, or the like.

In some embodiments, the alcohol-based solvent may include a secondary alcohol. Examples of the secondary alcohol include 2-propanol, 2-butanol, 2-pentanol, 3-pentanol, or 3-methyl-2-butanol, preferably may include 2-propanol.

In some embodiments, the alcohol-based solvent may include at least one selected from the group consisting of ethanol, 1-propanol, 2-propanol, 1-butanol and 1-pentanol.

In some embodiments, the alcohol-based solvent may include 2-propanol, and an alcohol-based solvent different from 2-propanol. For example, the alcohol-based solvent may include 2-propanol, and ethanol, 1-propanol, 1-butanol and/or 1-pentanol.

For example, the alcohol having 2 or 3 carbon atoms have a low boiling point, and thus may not remain on a surface of a semiconductor substrate after a cleaning process. Accordingly. a production yield of a semiconductor device may be increased.

In some embodiments, the alcohol-based solvent may include an alcohol having a boiling point of 110° C. or lower. For example, the alcohol having a boiling point of 110° C. or lower may include ethanol, 1-propanol, 2-propanol, 2-butanol, isobutanol, tert-butanol, tert-amyl alcohol, or the like.

For example, the alcohol having a boiling point of 110° C. or lower may be vaporized at a lower temperature, and thus may not remain on the surface of the semiconductor substrate after the cleaning process.

In some embodiments, a vapor pressure of the alcohol-based solvent at 25° C. may be 0.5 kPa or higher. For example, the alcohol having a vapor pressure of 0.5 kPa or higher at 25° C. may include ethanol, 1-propanol, 2-propanol, 1-butanol, 2-butanol, isobutanol, tert-butanol, 2-pentanol, 3-pentanol, tert-amyl alcohol, 2,2-dimethyl-1-propanol, or the like. These may be used alone or in a combination of two or more therefrom.

For example, the alcohol having a vapor pressure of 0.5 kPa or higher at 25° C. may be vaporized more easily, and may not remain on the surface of the semiconductor substrate after the cleaning process.

In example embodiments, a content of the alcohol-based solvent based on a total weight of the composition may be 99 wt % or more, and less than 100 wt %. In some embodiments, the content of the alcohol-based solvent based on the total weight of the composition may be 99.9 wt % or more and less than 100 wt %, 99.95 wt % or more and less than 100 wt %, or 99.99 wt % or more and less than 100 wt %.

In some embodiments, a content of 2-propanol based on the total weight of the composition may be 99 wt % or more, and less than 100 wt %. In an embodiment, the content of 2-propanol based on the total weight of the composition may be 99.9 wt % or more and less than 100 wt %, 99.95 wt % or more and less than 100 wt %, or 99.99 wt % or more and less than 100 wt %.

In some embodiments, the cleaning composition may include an alcohol-based solvent different from 2-propanol, as a remainder excluding the content of 2-propanol and the unsaturated carbonyl compound. For example, the cleaning composition may include the unsaturated carbonyl compound in an amount described below and 2-propanol in the amount described above, and may include the alcohol-based solvent different from the 2-propanol in a remaining amount.

The term “remainder or remaining amount” as used herein refers to a variable amount that may be changed depending on an addition of another component. For example, the cleaning composition may further include an organic solvent other than the alcohol-based solvent within a range in which the action of the alcohol-based solvent and the unsaturated carbonyl compound may not be hindered.

In example embodiments, the cleaning composition may include the unsaturated carbonyl compound. The unsaturated carbonyl compound may refer to a compound that contains both a carbon-carbon unsaturated bond (e.g., a double bond) and a carbonyl bond in a molecule.

In example embodiments, the unsaturated carbonyl compound may have the carbon-carbon unsaturated bond in an aliphatic or alicyclic hydrocarbon chain. For example, a compound that contains an unsaturated bond only in an aromatic ring may not be included in the unsaturated carbonyl compound.

The unsaturated carbonyl compound may be included so that watermarks caused by washing with water (e.g., ultrapure water or deionized water) prior to the cleaning process using the cleaning solution may be removed or reduced. Accordingly, as photoresist residues are removed by the cleaning composition, the watermarks may also be removed/reduced.

In some embodiments, the unsaturated carbonyl compound may have 3 to 10 carbon atoms. For example, if the carbon atoms of the unsaturated carbonyl compound increase excessively, the photoresist pattern may be dissolved to generate photoresist residues during the cleaning process.

In an embodiment, the unsaturated carbonyl compound may have 3 to 8 carbon atoms, 3 to 7 carbon atoms, or 3 to 6 carbon atoms.

In example embodiments, the unsaturated carbonyl compound may include mesityl oxide, methyl vinyl ketone, acrolein, methyl acrylate, acrylamide, maleic acid, fumaric acid, or the like. These may be used alone or in combination of two or more therefrom.

In some embodiments, the unsaturated carbonyl compound may include mesityl oxide, methyl vinyl ketone, and/or methyl acrylate. In this case, removal of the watermarks and particles by the cleaning process may be performed more efficiently. In an embodiment, the unsaturated carbonyl compound may include mesityl oxide.

In example embodiments, a content of the unsaturated carbonyl compound may be greater than 0, and 1 ppb or less based on the total weight of the cleaning composition. If the content of the unsaturated carbonyl compound exceeds 1 ppb, the watermark removal property may be degraded, and residues (particles) generated by the cleaning process may be increased.

Preferably, the content of the unsaturated carbonyl compound may be in a range from 0.1 ppt to 1 ppb, from 0.1 ppt to 0.5 ppb, or from 0.1 ppt to 10 ppt based on the total weight of the cleaning composition.

In the above content range, the watermark removal property may be efficiently implemented through the unsaturated carbonyl compound without degrading solubility of the photoresist residues by the cleaning composition.

In some embodiments, the unsaturated carbonyl compound may be added as a separate additive to the alcohol-based solvent to prepare the cleaning composition.

In some embodiments, the unsaturated carbonyl compound may be generated through a conversion reaction of alcohol during the preparation of the alcohol-based solvent. For example, the unsaturated carbonyl compound may be generated by converting a byproduct such as a ketone (e.g., acetone) included in the alcohol-based solvent.

In an embodiment, the ketone may be reacted with an alcohol in the alcohol-based solvent to generate the unsaturated carbonyl compound. For example, when producing the alcohol-based solvent such as IPA through hydrogenation of acetone, unreacted acetone or acetone byproducts may be converted into the unsaturated carbonyl compound, so that the unsaturated carbonyl compound may be included in the cleaning composition.

### <Method of Forming Photoresist Pattern>

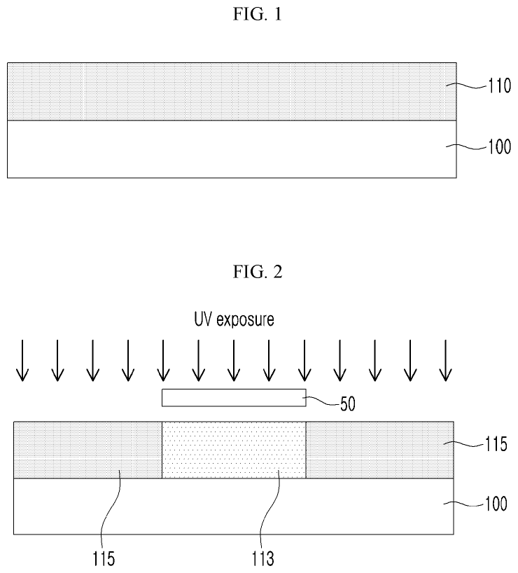

FIGS. 1 to 4 are schematic cross-sectional views for describing a method of forming a pattern according to embodiments. For example, in FIGS. 1 to 4, a method of forming a pattern using a negative photoresist is provided.

However, the cleaning composition according to embodiments is not limited to the processes of FIGS. 1 to 4, and may also be used in a pattern formation process using a positive photoresist.

Referring to FIG. 1, a photoresist layer 110 may be formed by coating a photoresist material on a substrate 100.

The substrate 100 may include a semiconductor material such as single crystal silicon or single crystal germanium. The substrate 100 may be formed to include polysilicon.

In some embodiments, a soft baking process may be performed after forming the photoresist layer 110. Accordingly, an organic solvent included in the photoresist layer 110 may be evaporated.

Referring to FIG. 2, a non-exposed portion 113 and an exposed portion 115 may be formed on the substrate 100 by an exposure process. The exposure process may be performed using a light source (e.g., a UV light source such as an EUV light source, a KrF laser, etc.) and an exposure mask 50.

Light passing through the exposure mask 50 may be irradiated to the photoresist layer 110. Accordingly, the photoresist layer 110 may have the non-exposed portion 113 and the exposed portion 115.

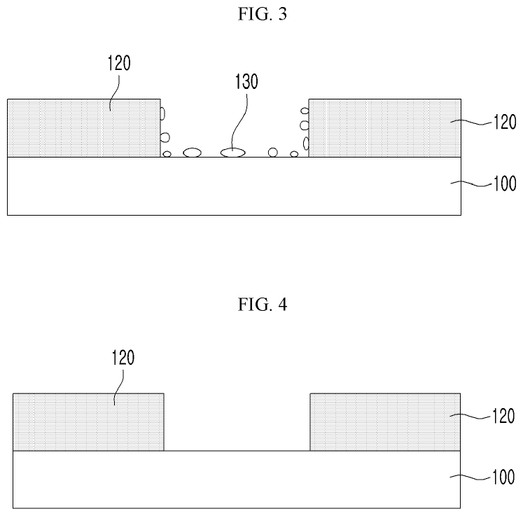

Referring to FIG. 3, a photoresist pattern 120 may be formed on the substrate 100 by a developing process. For example, the non-exposed portion 113 may be removed from the substrate 100 using a developer solution to form the photoresist pattern 120 including the exposed portion 115. The developer solution may be an aqueous tetramethylammonium hydroxide (TMAH) solution.

FIG. 3 illustrates a pattern formation process using a negative photoresist, but the pattern formation is not limited thereto. For example, the pattern formation process may be performed using a positive photoresist. In this case, the exposed portion 115 may be removed, and a photoresist pattern may be formed from the non-exposed portion 113.

In some embodiments, a post-baking process may be further performed after the exposure process or after the development process.

A developing residue 130 may be present on the substrate 100 after the developing process. The developing residue 130 may be an undeveloped photoresist or a developing solution residue. When the developing residue 130 remains on the substrate 100 or the photoresist pattern 120, defects may occur during a fabrication of a semiconductor device.

Referring to FIG. 4, the above-described cleaning composition according to embodiments may be applied or immersed on the substrate 100. Accordingly, the developing residue 130 formed on the substrate 100 or the photoresist pattern 120 may be removed.

The cleaning process may be performed by applying the cleaning composition according to the above-described embodiments described to the substrate 100 under commonly known cleaning conditions.

In some embodiments, a cleaning temperature may be in a range from 25° C. to 70° C., preferably from 25° C. to 50° C. A residence time of the substrate 100 when immersed in the cleaning composition may be in a range from about 5 seconds to 10 minutes, preferably from 10 seconds to 5 minutes.

In some embodiments, in the cleaning process, a first cleaning (washing with water) of removing the developing residue using deionized water may be performed, and then a second cleaning using the cleaning composition according to the above-described embodiments may be performed.

The first cleaning may cause the watermarks on the substrate 100. As described above, the cleaning composition may include the alcohol-based solvent and the unsaturated carbonyl compound, and may remove the watermarks while removing the developing residue 130. Accordingly, resolution and reliability of the photo-lithography process using the photoresist pattern 120 may be enhanced, and a target pattern with a fine line width may be obtained.

In addition to the pattern formation process using a photoresist, the cleaning composition according to embodiments may be used for cleaning an electronic device such as a semiconductor or a display, and may also be used for manufacturing various devices (an electric device such as a touch sensor, a display device, etc.) in which the cleaning process is performed.

Hereinafter, preferred embodiments are provided to help understanding of the present invention, but these embodiments are merely illustrative of the present invention and do not limit the scope of the attached patent claims, and it is obvious to those skilled in the art that various changes and modifications to the embodiments are possible within the scope of the present invention. These modifications are to be interpreted as being within the scope of the attached claims.

### Experimental Example

The cleaning compositions of Examples and Comparative Examples were prepared by mixing components with corresponding contents shown in Table 1 below. The content of each component is expressed based on a total weight of the cleaning composition.

### Evaluation of Watermark and Particle Removal Properties

100 mL of the cleaning compositions of Examples and Comparative Examples were placed in a bath (Marangoni Dryer) filled with 10 L of ultrapure water and left for 5 minutes. A 4-inch Si wafer was immersed in the bath and slowly lifted out of the bath.

Thereafter, a wafer surface was observed using an optical microscope to evaluate watermark and particle generation as follows.

### <Evaluation on Watermark Removal Property>

⊚: No watermark observed
◯: 1 or more, and less than 5 watermarks observed
Δ: 5 or more, and less than 20 watermarks observed
X: 20 or more watermarks observed

### <Evaluation on Particle Removal>

⊚: No particles observed
◯: 1 or more, and less than 5 particles observed
Δ: 5 or more, and less than 20 particles observed
X: 20 or more particles observed

The evaluation results are shown in Table 1 below.

TABLE 1

| | unsaturated | | | | | |
|---|---|---|---|---|---|---|
| | carbonyl | | alcohol-based | | | |
| | compound | | solvent | | water- | par- |
| | type | content | type | content | marks | ticles |
| Example 1 | A1 | 0.1 ppt | B1 | remainder | ⊚ | ⊚ |
| Example 2 | A1 | 1 ppt | B1 | remainder | ⊚ | ⊚ |
| Example 3 | A1 | 5 ppt | B1 | remainder | ⊚ | ⊚ |
| Example 4 | A1 | 10 ppt | B1 | remainder | ⊚ | ⊚ |
| Example 5 | A1 | 0.5 ppb | B1 | remainder | ⊚ | ⊚ |
| Example 6 | A1 | 1 ppb | B1 | remainder | ⊚ | ⊚ |
| Example 7 | A1 | 10 ppt | B1 | 99.99 wt % | ⊚ | ⊚ |
| | | | B2 | remainder | | |
| Example 8 | A1 | 10 ppt | B1 | 99.99 wt % | ⊚ | ⊚ |
| | | | B3 | remainder | | |
| Example 9 | A1 | 10 ppt | B1 | 99.99 wt % | ⊚ | ⊚ |
| | | | B4 | remainder | | |
| Example 10 | A1 | 10 ppt | B1 | 99.99 wt % | ⊚ | ⊚ |
| | | | B5 | remainder | | |
| Example 11 | A2 | 0.1 ppt | B1 | remainder | ⊚ | ⊚ |
| Example 12 | A3 | 1 ppt | B1 | remainder | ⊚ | ⊚ |
| Example 13 | A2 | 5 ppt | B1 | remainder | ⊚ | ⊚ |
| Example 14 | A2 | 10 ppt | B1 | remainder | ⊚ | ⊚ |
| Example 15 | A2 | 0.5 ppb | B1 | remainder | ⊚ | ⊚ |
| Example 16 | A2 | 1 ppb | B1 | remainder | ⊚ | ⊚ |
| Example 17 | A2 | 10 ppt | B1 | 99.99 wt % | ⊚ | ⊚ |
| | | | B2 | remainder | | |
| Example 18 | A2 | 10 ppt | B1 | 99.99 wt % | ⊚ | ⊚ |
| | | | B3 | remainder | | |
| Example 19 | A2 | 10 ppt | B1 | 99.99 wt % | ⊚ | ⊚ |
| | | | B4 | remainder | | |
| Example 20 | A2 | 10 ppt | B1 | 99.99 wt % | ⊚ | ⊚ |
| | | | B5 | remainder | | |
| Example 21 | A3 | 0.1 ppt | B1 | remainder | O | O |
| Example 22 | A3 | 1 ppt | B1 | remainder | O | O |
| Example 23 | A3 | 5 ppt | B1 | remainder | O | O |
| Example 24 | A3 | 10 ppt | B1 | remainder | O | O |
| Example 25 | A3 | 0.5 ppb | B1 | remainder | O | O |
| Example 26 | A3 | 1 ppb | B1 | remainder | O | O |
| Example 27 | A3 | 10 ppt | B1 | 99.99 wt % | O | O |
| | | | B2 | remainder | | |
| Example 28 | A3 | 10 ppt | B1 | 99.99 wt % | O | O |
| | | | B3 | remainder | | |
| Example 29 | A3 | 10 ppt | B1 | 99.99 wt % | O | O |
| | | | B4 | remainder | | |
| Example 30 | A3 | 10 ppt | B1 | 99.99 wt % | O | O |
| | | | B5 | remainder | | |
| Example 31 | A4 | 0.1 ppt | B1 | remainder | ⊚ | ⊚ |
| Example 32 | A4 | 1 ppt | B1 | remainder | ⊚ | ⊚ |
| Example 33 | A4 | 5 ppt | B1 | remainder | ⊚ | ⊚ |
| Example 34 | A4 | 10 ppt | B1 | remainder | ⊚ | ⊚ |
| Example 35 | A4 | 0.5 ppb | B1 | remainder | ⊚ | ⊚ |
| Example 36 | A4 | 1 ppb | B1 | remainder | ⊚ | ⊚ |
| Example 37 | A4 | 10 ppt | B1 | 99.99 wt % | ⊚ | ⊚ |
| | | | B2 | remainder | | |
| Example 38 | A4 | 10 ppt | B1 | 99.99 wt % | ⊚ | ⊚ |
| | | | B3 | remainder | | |
| Example 39 | A4 | 10 ppt | B1 | 99.99 wt % | ⊚ | ⊚ |
| | | | B4 | remainder | | |
| Example 40 | A4 | 10 ppt | B1 | 99.99 wt % | ⊚ | ⊚ |
| | | | B5 | remainder | | |
| Example 41 | A5 | 0.1 ppt | B1 | remainder | O | O |
| Example 42 | A5 | 1 ppt | B1 | remainder | O | O |
| Example 43 | A5 | 5 ppt | B1 | remainder | O | O |
| Example 44 | A5 | 10 ppt | B1 | remainder | O | O |
| Example 45 | A5 | 0.5 ppb | B1 | remainder | O | O |
| Example 46 | A5 | 1 ppb | B1 | remainder | O | O |
| Example 47 | A5 | 10 ppt | B1 | 99.99 wt % | O | O |
| | | | B2 | remainder | | |
| Example 48 | A5 | 10 ppt | B1 | 99.99 wt % | O | O |
| | | | B3 | remainder | | |
| Example 49 | A5 | 10 ppt | B1 | 99.99 wt % | O | O |
| | | | B4 | remainder | | |
| Example 50 | A5 | 10 ppt | B1 | 99.99 wt % | O | O |
| | | | B5 | remainder | | |
| Example 51 | A1 | 0.05 ppt | B1 | remainder | Δ | O |
| Example 52 | A1 | 10 ppt | B6 | remainder | Δ | O |
| Comparative | A1 | 1.5 ppb | B1 | remainder | Δ | Δ |
| Example 1 | | | | | | |
| Comparative | A1 | 2 ppb | B1 | remainder | Δ | Δ |
| Example 2 | | | | | | |
| Comparative | A2 | 2 ppb | B1 | remainder | Δ | Δ |
| Example 3 | | | | | | |
| Comparative | A3 | 2 ppb | B1 | remainder | Δ | Δ |
| Example 4 | | | | | | |
| Comparative | A4 | 2 ppb | B1 | remainder | Δ | Δ |
| Example 5 | | | | | | |
| Comparative | A5 | 2 ppb | B1 | remainder | Δ | Δ |
| Example 6 | | | | | | |
| Comparative | — | — | B1 | 100 wt % | X | X |
| Example 7 | | | | | | |

The components shown in Table 1 are as follows:
A1: mesityl oxide (Sigma-Aldrich)
A2: methyl vinyl ketone (Sigma-Aldrich)
A3: acrolein (Sigma-Aldrich)
A4: methyl acrylate (Sigma-Aldrich)
A5: acryl amide (Sigma-Aldrich)
B1: 2-propanol
B2: 1-propanol
B3: ethanol
B4: 1-butanol
B5: 1-pentanol
B6: 1-hexanol

Referring to Table 1, the cleaning compositions of Examples including the alcohol-based solvent and the unsaturated carbonyl compound provided improved watermark and particle removal capabilities.

In Comparative Example 7 where the unsaturated carbonyl compound was not included, generation of watermarks and particles was significantly increased. In Comparative Examples 1 to 6 where the content of the unsaturated carbonyl compound was excessively increased, generation of watermarks and particles was increased compared to those in Examples.

Referring to Example 51, generation of watermarks was increased compared to those from other Examples as the content of unsaturated carbonyl compounds was relatively reduced.

Referring to Example 52 where the alcohol-based solvent having more than 5 carbon atoms was used, generation of watermarks was increased compared to those from other Examples

What is claimed is:

1. A cleaning composition comprising:
an alcohol-based solvent; and
an unsaturated carbonyl compound,
wherein a content of the unsaturated carbonyl compound is greater than 0, and 1 ppb or less based on a total weight of the composition.

2. The cleaning composition of claim 1, wherein the content of the unsaturated carbonyl compound is in a range from 0.1 ppt to 1 ppb based on the total weight of the composition.

3. The cleaning composition of claim 1, wherein the unsaturated carbonyl compound has 3 to 10 carbon atoms.

4. The cleaning composition of claim 1, wherein the unsaturated carbonyl compound comprises at least one selected from the group consisting of mesityl oxide, methyl vinyl ketone, acrolein, methyl acrylate, acrylamide, maleic acid and fumaric acid.

5. The cleaning composition of claim 1, wherein the unsaturated carbonyl compound comprises mesityl oxide.

6. The cleaning composition of claim 1, wherein the alcohol-based solvent comprises an alcohol having 2 to 5 carbon atoms.

7. The cleaning composition of claim 1, wherein the alcohol-based solvent comprises at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.

8. The cleaning composition of claim 1, wherein the alcohol-based solvent comprises 2-propanol.

9. The cleaning composition of claim 8, wherein the alcohol-based solvent further comprises at least one selected from the group consisting of ethanol, 1-propanol, 1-butanol and 1-pentanol.

10. The cleaning composition of claim 1, wherein a boiling point of the alcohol-based solvent is 110° C. or less, and a vapor pressure of the alcohol-based solvent at 25° C. is 0.5 kPa or higher.

11. The cleaning composition of claim 1, wherein a content of the alcohol-based solvent is 99 wt % or more, and less than 100 wt % based on the total weight of the composition.

12. A method of forming a photoresist pattern, the method comprising:
forming a photoresist layer on a substrate;
partially removing the photoresist layer to form a photoresist pattern; and
cleaning the substrate on which the photoresist pattern is formed using the cleaning composition of claim 1.

13. The method of claim 12, further comprising washing the substrate on which the photoresist pattern is formed with water prior to the cleaning using the cleaning composition.
